(19) United States
(12) Patent Application Publication
(10) Pub. No.: US 2008/0272488 A1
(43) Pub. Date: Nov. 6, 2008

(54) Semiconductor Device

(75) Inventors: Osamu Miyata, Kyoto (JP); Takuya Kadoguchi, Osaka (JP); Masaki Kasai, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/663,856

(22) PCT Filed: Sep. 26, 2005
(86) PCT No.: PCT/JP05/17587

§ 371 Date: Aug. 28, 2007

(30) Foreign Application Priority Data
Sep. 28, 2004 (JP) 2004-282016
Oct. 28, 2004 (JP) 2004-314395
May 12, 2005 (JP) 2005-139955

(51) Int. Cl. H01L 23/52

(52) U.S. Cl. 257/738; 257/E23.141

(57) ABSTRACT

A semiconductor device according to the present invention includes a semiconductor chip having a functional surface formed with a functional element, an electrode pad provided directly on the functional element on the functional surface of the semiconductor chip, a protective resin layer laminated on the functional surface of the semiconductor chip, an external connection terminal provided on the protective resin layer in opposed relation to the electrode pad, and a post extending through the protective resin layer in a direction in which the electrode pad and the external connection terminal are opposed to each other for connection between the electrode pad and the external connection terminal.

### BACKGROUND OF THE INVENTION

1. Field of the Invention

The present invention relates to a semiconductor device and, particularly, to a semiconductor device produced by a WL-CSP (Wafer Level-Chip Scale Package).

2. Description of the Related Art

With higher performance and multifunctional semiconductor devices, WL-CSPs (Wafer Level-Chip Scale Packages) have been recently put into practical use. The WL-CSPs are produced by completing the packaging of chips on a wafer level and dicing the wafer and, therefore, each have a package size which is equivalent to the size of the chip.

As shown in FIG. 5, a semiconductor device produced by the prior-art WL-CSP (WL-CSP semiconductor device) includes a semiconductor chip 101 having a surface formed with a functional element 101a, an interlevel insulation film 102 laminated on the surface of the semiconductor chip 101, an internal interconnection 103 provided on the interlevel insulation film 102, a surface protective film 104 laminated on the interlevel insulation film 102 and the internal interconnection 103, a rewiring 105 provided on the surface protective film 104, a sealing resin layer 106 laminated on the surface protective film 104 and the rewiring 105, and a solder ball 107 provided on the sealing resin layer 106 for external connection.

The interlevel insulation film 102 has a connection opening 108 directly on the functional element 101a, and the internal interconnection 103 is connected to the functional element 101a through the connection opening 108. The internal interconnection 103 extends from the connection opening 108 to a peripheral area of the semiconductor chip 101 on the interlevel insulation film 102. The surface protective film 104 has a pad opening 110 in which a part of the internal interconnection 103 is present as an electrode pad 109 in a peripheral area of the surface protective film 104. The rewiring 105 is connected to the internal interconnection 103 (electrode pad 109) through the pad opening 110. The rewiring 105 extends to a position opposed to the solder ball 107 with the intervention of the sealing resin layer 106, and a distal end of the rewiring 105 is connected to the solder ball 107 via a post 111 which extends through the sealing resin layer 106.

Therefore, an interconnection (including the internal interconnection 103 and the rewiring 105) should be routed from the position of the function element 101a to the position opposed to the solder ball 107 via the electrode pad 109 in the prior-art WL-CSP semiconductor device, thereby complicating the construction of the semiconductor device and the production process for the semiconductor device.

### SUMMARY OF THE INVENTION

It is therefore an object of the present invention to provide a semiconductor device which does not require routing of an interconnection for electrical connection between a functional element and an external connection terminal.

The semiconductor device according to the present invention comprises a semiconductor chip having a functional surface formed with a functional element, an electrode pad provided directly on the functional element on the functional surface of the semiconductor chip, a protective resin layer provided on the functional surface of the semiconductor chip, an external connection terminal provided on the protective resin layer in opposed relation to the electrode pad, and a post extending through the protective resin layer in an opposing direction in which the electrode pad and the external connection terminal are opposed to each other for connection between the electrode pad and the external connection terminal.

With this arrangement, the electrode pad is provided directly on the functional element, and the external connection terminal is disposed in opposed relation to the electrode pad on the protective resin layer. The electrode pad and the external connection terminal are connected to each other via the post extending through the protective resin layer in their opposing direction. Therefore, there is no need to route an interconnection such as a rewiring for electrical connection between the functional element and the external connection terminal. As a result, the construction of the semiconductor device and the production process for the semiconductor device can be simplified, thereby reducing the costs of the semiconductor device. Further, a distance between the functional element (electrode pad) and the external connection terminal is reduced, so that device characteristics (operating speed and the like) can be improved.

The size of the post as seen perpendicularly to the functional surface of the semiconductor chip may be smaller than the size of the electrode pad as seen in the same direction. In other words, the post may be formed as having a smaller size than the electrode pad as seen perpendicularly to the functional surface of the semiconductor chip. In this case, an end face of the post adjacent to the electrode pad can be entirely connected to the electrode pad. This prevents intervention of a surface protective film and the like between the post and the electrode pad. As a result, even if a stress is exerted on the external connection terminal and the post when the semiconductor device is bonded to a wiring board or the like, the surface protective film and the like are prevented from being damaged by the stress.

The size of the post as seen perpendicularly to the functional surface of the semiconductor chip may be not smaller than the size of the electrode pad as seen in the same direction. In other words, the post may be formed as having a size which is substantially equal to or greater than the size of the electrode pad as seen perpendicularly to the functional surface of the semiconductor chip. In this case, even if a stress is exerted on the external connection terminal when the semiconductor device is bonded to the wiring board or the like, the stress is absorbed by the post. Therefore, the electrode pad and the functional element are prevented from being damaged.

The post is preferably composed of silver, tin or gold. Silver, tin and gold each have a greater ductility than copper. Therefore, the post of silver, tin or gold is more deformable than a copper post when receiving the stress, so that the stress can be alleviated by the deformation. Therefore, the post may have a reduced length as compared with the copper post. If the post has a reduced length, the time required for plating for formation of the post can be reduced. In addition, a liquid resist can be used for the formation of the post. Therefore, the post can be more easily formed. Further, the thickness of the semiconductor device (as measured perpendicularly to the functional surface of the semiconductor chip) can be reduced.

Where the post is composed of gold which is a very stable element, an adhesive force between the post and the protective resin layer (a bonding force between gold and a resin) is small. Therefore, even if the semiconductor chip and the protective resin layer are displaced from each other due to a difference in thermal expansion coefficient therebetween, a shear stress exerted between the post and the electrode pad by the displacement is absorbed by the deformation of the post. Therefore, the post and the electrode pad are prevented from being electrically disconnected.

The electrode pad may include a plurality of electrode pads which are arranged in a grid array.

The semiconductor device may be a semiconductor device produced by a WL-CSP.

The foregoing and other objects, features and effects of the present invention will become more apparent from the following detailed description of embodiments with reference to the attached drawings.

### BRIEF DESCRIPTION OF THE DRAWINGS

FIG. 1 is a plan view schematically illustrating the construction of a semiconductor device according to one embodiment of the present invention;

FIG. 2 is a schematic sectional view of the semiconductor device taken along a sectional line A-A in FIG. 1;

FIG. 3 is a diagram illustrating an exemplary arrangement of electrode pads on a functional surface of a semiconductor chip of the semiconductor device shown in FIG. 1;

FIG. 4 is a sectional view schematically illustrating the construction of a semiconductor device according to another embodiment of the present invention; and

FIG. 5 is a sectional view schematically illustrating the construction of a prior-art WL-CSP semiconductor device.

### DESCRIPTION OF THE PREFERRED EMBODIMENTS

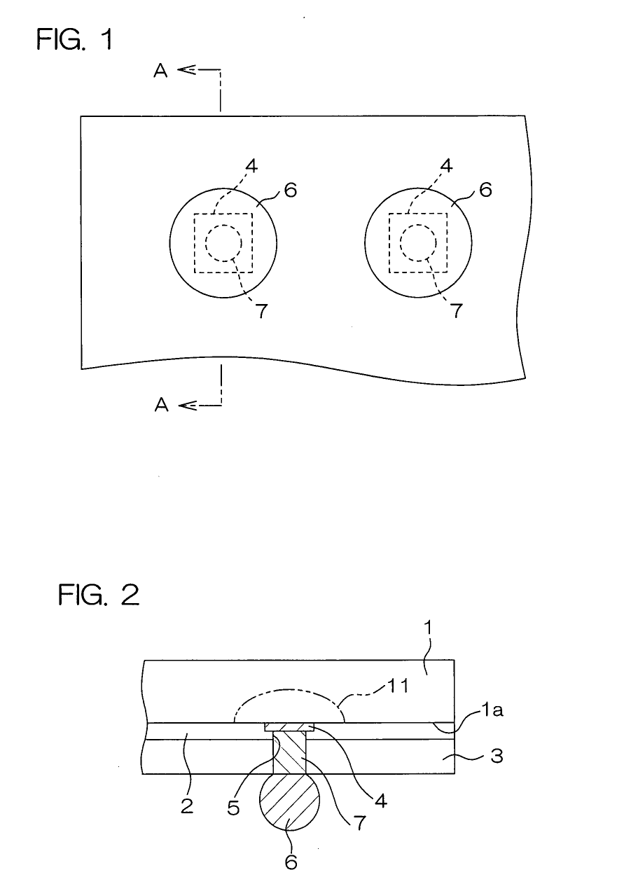

FIG. 1 is a plan view illustrating the construction of a semiconductor device according to one embodiment of the present invention, and FIG. 2 is a schematic sectional view of the semiconductor device taken along a sectional line A-A in FIG. 1.

This semiconductor device is a semiconductor device produced by a WL-CSP (Wafer Level-Chip Scale Package), and includes a semiconductor chip 1 having a functional surface 1a formed with functional elements 11, a surface protective film 2 laminated on the functional surface 1a of the semiconductor chip 1, and a protective resin layer 3 laminated on the surface protective film 2.

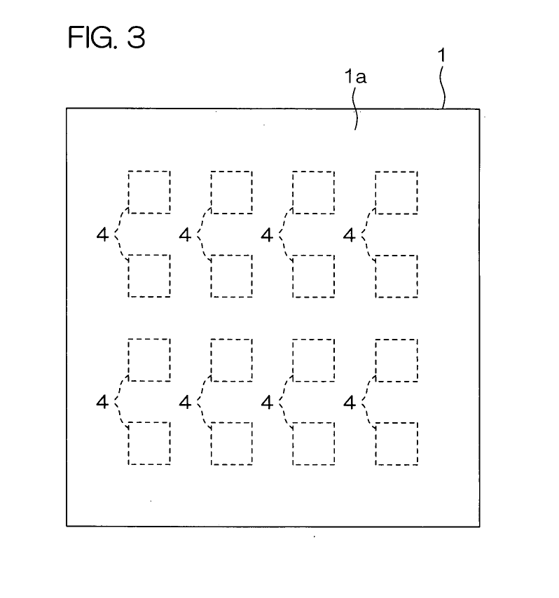

As shown in FIG. 3, a plurality of electrode pads 4 are generally equidistantly arranged in a grid array on the functional surface 1a of the semiconductor chip 1. The electrode pads 4 are each formed of aluminum in a rectangular plate shape. The electrode pads 4 are respectively disposed directly on the functional elements 11 formed in the functional surface 1a of the semiconductor chip 1. The surface protective film 2 has round openings 5 which are respectively opposed to the electrode pads 4 perpendicularly to the functional surface 1a. Center portions of the electrode pads 4 are exposed from the surface protective film 2 through the openings 5.

Metal balls 6 as external connection terminals for connection to a wiring board or the like (for external connection) are disposed on the protective resin layer 3 as being respectively opposed to the electrode pads 4 perpendicularly to the functional surface 1a. The metal balls 6 are each formed of a metal material such as solder in a ball shape.

Cylindrical posts 7 of copper are respectively provided between the electrode pads 4 and the metal balls 6 as extending through the protective resin layer 3. The posts 7 each have substantially the same diameter as the diameter of the openings 5, and have a smaller size than the electrode pads 4 as seen perpendicularly to the functional surface 1a of the semiconductor chip 1. The posts 7 each have one end connected to the metal ball 6 and the other end inserted in the opening 5 to be connected to the electrode pad 4.

Thus, the electrode pads 4 are respectively provided directly on the functional elements 11, and the metal balls 6 are disposed on the protective resin layer 3 as being respectively opposed to the electrode pads 4, whereby the electrode pads 4 are respectively connected to the metal balls 6 via the posts 7 extending through the protective resin layer 3 in an opposing direction in which the electrode pads 4 are opposed to the metal balls 6. Therefore, there is no need to route an interconnection including an internal interconnection, a rewiring and the like for the electrical connection between the functional elements 11 and the metal balls 6. As a result, the construction of the semiconductor device and the production process for the semiconductor device can be simplified, thereby reducing the costs of the semiconductor device. Further, distances between the functional elements 11 (electrode pads 4) and the metal balls 6 are reduced, so that device characteristics (operating speed and the like) can be improved.

Further, the posts 7 are each formed as having a smaller size than the electrode pads 4 as seen perpendicularly to the functional surface 1a of the semiconductor chip 1. Therefore, the surface protective film 2 does not intervene between the posts 7 and the electrode pads 4. Therefore, even if a stress is exerted on the metal balls 6 (posts 7) when the semiconductor device is bonded to a wiring board or the like, the surface protective film 2 is prevented from being damaged by the stress.

In this embodiment, the posts 7 are formed of copper. However, the material for the posts 7 is not limited to copper, but may be silver (Ag), tin (Sn) or gold (Au). The posts 7 formed of silver, tin or gold are more deformable than the copper posts 7 when receiving a stress, and the stress is alleviated by the deformation. Where the posts 7 are formed of copper, the posts 7 are each required to have a length (height) of 50 to 90 μm. Where the posts 7 are formed of silver, tin or gold, the posts 7 are each required to have a length of about 20 μm. If the posts 7 each have a smaller length, the time required for plating for the formation of the posts 7 can be reduced. In addition, a liquid resist can be used for the formation of the posts 7. Therefore, the posts 7 can be more easily formed. Further, the thickness of the semiconductor device (as measured perpendicularly to the functional surface 1a of the semiconductor chip 1) can be reduced.

Further, where the posts 7 are composed of gold which is a very stable element, an adhesive force between the posts 7 and the protective resin layer 3 (a bonding force between gold and a resin) is small. Therefore, even if the semiconductor chip 1 and the protective resin layer 3 are displaced from each other due to a difference in thermal expansion coefficient therebetween, a shear stress exerted between the posts 7 and the electrode pads 4 by the displacement is absorbed by the deformation of the posts 7. Therefore, the posts 7 and the electrode pads 4 are prevented from being electrically disconnected.

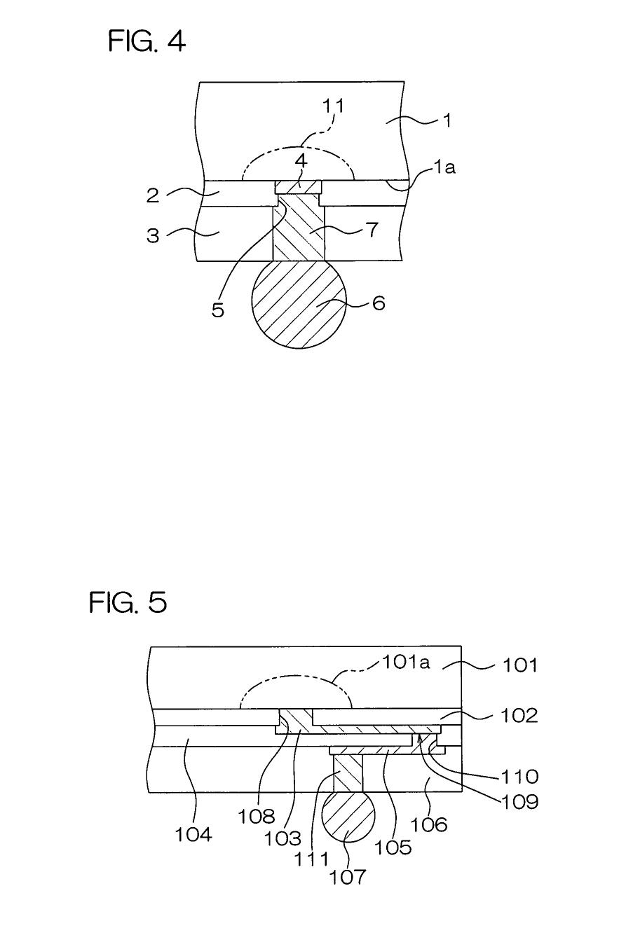

FIG. 4 is a sectional view schematically illustrating the construction of a semiconductor device according to another embodiment of the present invention. In FIG. 4, components corresponding to those shown in FIG. 2 will be denoted by the same reference characters as in FIG. 2. In the following explanation, only a difference from the aforementioned embodiment will be described, and the same arrangement as the aforementioned embodiment will not be described.

In the aforementioned embodiment, the posts 7 are each formed as having a smaller size than the electrode pads 4 as seen perpendicularly to the functional surface 1a of the semiconductor chip 1. In the semiconductor device according to this embodiment, in contrast, the posts 7 each have a greater size than the electrode pads 4 as seen perpendicularly to the functional surface 1a of the semiconductor chip 1.

With this arrangement, the posts 7 are each formed as having a greater size than the electrode pads 4 as seen perpendicularly to the functional surface 1a of the semiconductor chip 1. Therefore, even if a stress is exerted on the metal balls 6 when the semiconductor device is bonded to a wiring board or the like, the stress is absorbed by the posts 7. Therefore, the electrode pads 4 and the functional elements 11 are prevented from being damaged.

Although the posts 7 are each formed as having a greater size than the electrode pads 4 as seen perpendicularly to the functional surface 1a of the semiconductor chip 1 in this embodiment, the posts 7 may each have substantially the same size as the electrode pads 4 as seen perpendicularly to the functional surface 1a of the semiconductor chip 1. Even in this case, the effects described above can be provided.

While the present invention has thus been described in detail by way of the embodiments thereof, it should be understood that these embodiments are merely illustrative of the technical principles of the present invention but not limitative of the invention. The spirit and scope of the present invention are to be limited only by the appended claims.

For example, the shapes of the electrode pads 4, the openings 5 and the posts 7 are not particularly limited. The electrode pads 4 may each be formed in a round shape, and the posts 7 may each be formed in a columnar shape.

The electrode pads 4 may be generally equidistantly arranged along a peripheral edge of the semiconductor chip 1 in a rectangular frame shape.

This application corresponds to Japanese Patent Application No. 2004-282016 filed in the Japanese Patent Office on Sep. 28, 2004, Japanese Patent Application No. 2004-314395 filed in the Japanese Patent Office on Oct. 28, 2004, and Japanese Patent Application No. 2005-139955 filed in the Japanese Patent Office on May 12, 2005, the disclosure of which is incorporated herein by reference.

What is claimed is:

1. A semiconductor device comprising:
a semiconductor chip having a functional surface formed with a functional element;
an electrode pad provided directly on the functional element on the functional surface of the semiconductor chip;
a protective resin layer provided on the functional surface of the semiconductor chip;
an external connection terminal provided on the protective resin layer in opposed relation to the electrode pad; and
a post extending through the protective resin layer in a direction in which the electrode pad and the external connection terminal are opposed to each other for connection between the electrode pad and the external connection terminal.

2. A semiconductor device as set forth in claim 1, wherein a size of the post as seen perpendicularly to the functional surface of the semiconductor chip is smaller than a size of the electrode pad as seen in the same direction.

3. A semiconductor device as set forth in claim 1, wherein a size of the post as seen perpendicularly to the functional surface of the semiconductor chip is not smaller than a size of the electrode pad as seen in the same direction.

4. A semiconductor device as set forth in claim 1, wherein the post is composed of silver, tin or gold.

5. A semiconductor device as set forth in claim 1, wherein the electrode pad includes a plurality of electrode pads which are arranged in a grid array.

6. A semiconductor device as set forth in claim 1, which is a semiconductor device produced by a WL-CSP.
